(19) United States
(12) Patent Application Publication
(10) Pub. No.: US 2025/0151366 A1
(43) Pub. Date: May 8, 2025

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Zi-Ting Huang, Kaohsiung City (TW); Ching-Ling Lin, Kaohsiung City (TW); Wen-An Liang, Tainan City (TW)

(73) Assignee: UNITED MICROELECTRONICS CORP., Hsin-Chu City (TW)

(21) Appl. No.: 18/531,679

(22) Filed: Dec. 6, 2023

(30) Foreign Application Priority Data
Nov. 7, 2023 (TW) 112142800

(51) Int. Cl. H01L 29/423; H01L 29/66; H01L 29/78

(52) U.S. Cl. CPC H10D 64/514; H10D 30/024; H10D 30/62; H10D 64/017

(57) ABSTRACT

A method for fabricating semiconductor device includes the steps of first providing a substrate having a core region and an input/output (I/O) region and then forming a first metal gate on the core region and a second metal gate on the I/O region. Preferably, the first metal gate includes a first gate dielectric layer, the second metal gate includes a second gate dielectric layer, the first gate dielectric layer and the second gate dielectric layer having different shapes such that the first gate dielectric layer includes an I-shape and the second gate dielectric layer includes a U-shape.

### BACKGROUND OF THE INVENTION

### 1. Field of the Invention

The invention relates to a method for fabricating semiconductor device, and more particularly, to a method of forming gate dielectric layers having different shapes on different regions.

### 2. Description of the Prior Art

In current semiconductor industry, polysilicon has been widely used as a gap-filling material for fabricating gate electrode of metal-oxide-semiconductor (MOS) transistors. However, the conventional polysilicon gate also faced problems such as inferior performance due to boron penetration and unavoidable depletion effect which increases equivalent thickness of gate dielectric layer, reduces gate capacitance, and worsens driving force of the devices. In replacing polysilicon gates, work function metals have been developed to serve as a control electrode working in conjunction with high-K gate dielectric layers.

However, in current fabrication of high-k metal gate transistors, device regions such as input/output (I/O) region and core region are largely affected by the predetermined thickness of interfacial layer. For instance, voids are often formed as a result of epitaxial layer loss caused by wet etching process conducted during removal of polysilicon gates. Hence, how to resolve this issue has become an important task in this field.

### SUMMARY OF THE INVENTION

According to an embodiment of the present invention, a method for fabricating semiconductor device includes the steps of first providing a substrate having a core region and an input/output (I/O) region and then forming a first metal gate on the core region and a second metal gate on the I/O region. Preferably, the first metal gate includes a first gate dielectric layer, the second metal gate includes a second gate dielectric layer, the first gate dielectric layer and the second gate dielectric layer having different shapes such that the first gate dielectric layer includes an I-shape and the second gate dielectric layer includes a U-shape.

According to another aspect of the present invention, a semiconductor device includes a substrate having a core region and an input/output (I/O) region and a first metal gate on the core region and a second metal gate on the I/O region. Preferably, the first metal gate includes a first gate dielectric layer, the second metal gate includes a second gate dielectric layer, and the first gate dielectric layer and the second gate dielectric layer have different shapes.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-8 illustrate a method for fabricating a semiconductor device according to an embodiment of the present invention.

### DETAILED DESCRIPTION

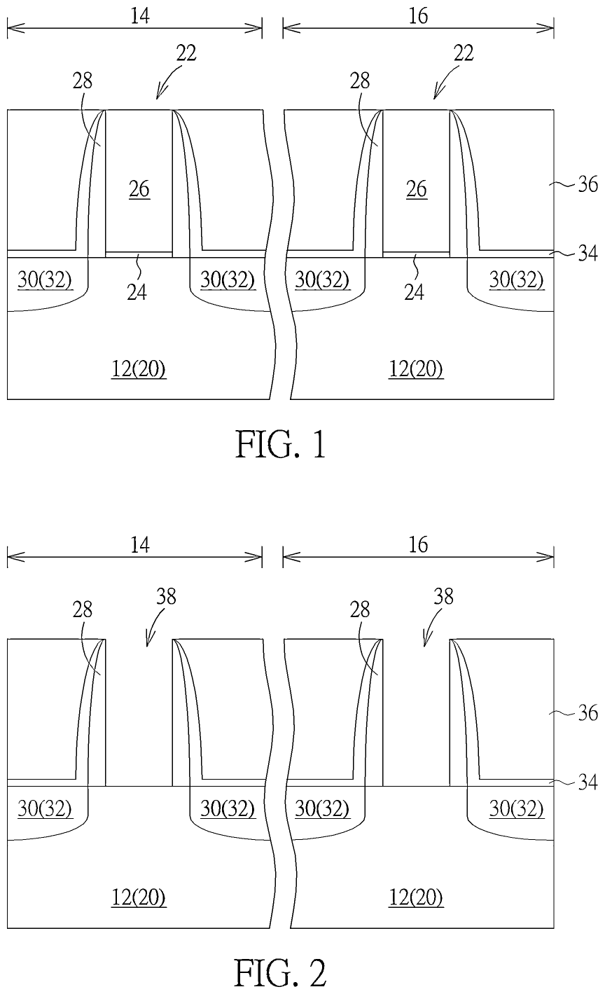

Referring to FIGS. 1-8, FIGS. 1-8 illustrate a method for fabricating a semiconductor device according to an embodiment of the present invention. As shown in FIG. 1, a substrate 12, such as a silicon substrate or silicon-on-insulator (SOI) substrate is provided, and a core region 14 and an input/output (I/O) region 16 are defined on the substrate 12. In this embodiment, the core region 14 and the I/O region 16 are transistor regions sharing same conductive type, such as all being PMOS regions or NMOS regions. Preferably, at least a fin-shaped structure 20 is formed on each of the core region 14 and I/O region 16 and the bottom of the fin-shaped structure 20 is surrounded by a shallow trench isolation (STI) (not shown) composed of silicon oxide. It should be noted that even though this embodiment pertains to a FinFET process, it would also be desirable to apply the process of this embodiment to a non-planar MOS transistor, which is also within the scope of the present invention.

The fin-shaped structure 20 of this embodiment is preferably obtained by a sidewall image transfer (SIT) process. For instance, a layout pattern is first input into a computer system and is modified through suitable calculation. The modified layout is then defined in a mask and further transferred to a layer of sacrificial layer on a substrate through a photolithographic and an etching process. In this way, several sacrificial layers distributed with a same spacing and of a same width are formed on a substrate. Each of the sacrificial layers may be stripe-shaped. Subsequently, a deposition process and an etching process are carried out such that spacers are formed on the sidewalls of the patterned sacrificial layers. In a next step, sacrificial layers can be removed completely by performing an etching process. Through the etching process, the pattern defined by the spacers can be transferred into the substrate underneath, and through additional fin cut processes, desirable pattern structures, such as stripe patterned fin-shaped structures could be obtained.

Alternatively, the fin-shaped structure 20 of this embodiment could also be obtained by first forming a patterned mask (not shown) on the substrate, 12, and through an etching process, the pattern of the patterned mask is transferred to the substrate 12 to form the fin-shaped structure 20. Moreover, the formation of the fin-shaped structure 20 could also be accomplished by first forming a patterned hard mask (not shown) on the substrate 12, and a semiconductor layer composed of silicon germanium is grown from the substrate 12 through exposed patterned hard mask via selective epitaxial growth process to form the corresponding fin-shaped structure 20. These approaches for forming fin-shaped structure 20 are all within the scope of the present invention.

Next, gate structures 22 or dummy gates are formed on the core region 14 and I/O region 16 of the substrate 12. In this embodiment, the formation of the gate structures 22 could be accomplished by sequentially depositing a gate dielectric layer 24, a gate material layer 26, and a selective hard mask (not shown) on the substrate 12, conducting a pattern transfer process by using a patterned resist (not shown) as mask to remove part of the gate material layer 26 and part of the gate dielectric layer 24, and then stripping the patterned resist to form gate structures 22 on the fin-shaped structure 20 on the core region 14 and I/O region 16. Each of the gate structures 22 preferably includes a patterned gate dielectric layer 24 and a patterned material layer 26, in which the gate dielectric layer 24 includes silicon oxide and the gate material layer 26 includes polysilicon, but not limited thereto.

Next, at least a spacer 28 is formed on sidewalls of each gate structure 22, a source/drain region 30 and/or epitaxial layer 32 are formed in the fin-shaped structure 20 and/or substrate 12 adjacent to two sides of the spacer 28, and a selective silicide (not shown) is formed on the surface of the source/drain region 30 and/or epitaxial layer. In this embodiment, the spacer 28 could be a single spacer or a composite spacer. For instance, the spacer 28 could further include an offset spacer (not shown) and a main spacer (not shown), and the spacer 28 could be selected from the group consisting of SiO₂, SIN, SiON, and SiCN. The source/drain regions 30 and epitaxial layers 32 could include different dopants or different material depending on the type of transistor being fabricated. For instance, the source/drain regions 30 could include p-type or n-type dopants and the epitaxial layers could include SiGe, SiC, or SiP.

Next, a contact etch stop layer (CESL) 34 composed of silicon nitride could be selectively formed on the substrate 12 to cover the gate structures 22, and an interlayer dielectric layer 36 is formed on the CESL 34. Next, a planarizing process, such as chemical mechanical polishing (CMP) process is conducted to remove part of the ILD layer 36 and part of the CESL 34 to expose the gate material layer 26 composed of polysilicon so that the top surfaces of the gate material layer 26, CESL 34, and ILD layer 36 on each of the core region 14 and I/O region 16 are coplanar.

Next, as shown in FIG. 2, a replacement metal gate (RMG) process is conducted to transform the gate structures 22 into metal gates. For instance, a selective dry etching or wet etching process could be conducted by using etchant including ammonium hydroxide (NH₄OH) or tetramethylammonium hydroxide (TMAH) to remove the gate material layers 26 and gate dielectric layers 24 in the gate structures 22 for forming recesses 38 in the ILD layer 36. Since the gate dielectric layers 34 formed on the core region 14 and I/O region 16 before forming the recesses 38 are made of thinner silicon oxide, it would be desirable to completely remove the gate dielectric layers 24 on the core region 14 and I/O region 16 while the gate material layers 26 made of polysilicon are removed for exposing the surface of the substrate 12.

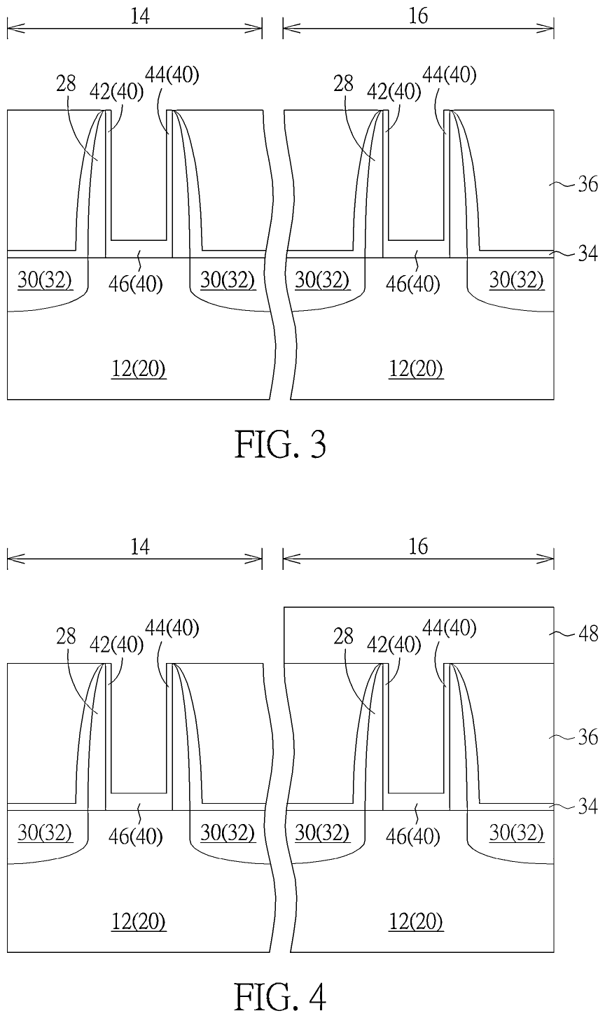

Next, as shown in FIG. 3, an oxide growth process such as a rapid thermal oxidation (RTO) process or an in-situ steam generation (ISSG) process is conducted to form a gate dielectric layer made of silicon oxide in the recesses 38 on the core region 14 and I/O region 16.

It should be noted that the oxide growth process conducted at this stage preferably adjusts the volume and duration of the oxygen injected so that the oxygen would react inner sidewalls of the spacer 28 and surface of the fin-shaped structure 20 or substrate 12 to form gate dielectric layers 40 having U-shape cross-section. Preferably, the gate dielectric layer 40 formed on the core region 14 and the gate dielectric layer 40 formed on the I/O region 16 have same thickness and the thickness of the gate dielectric layer 40 directly contacting inner sidewalls of the spacer 28 is less than the thickness of the gate dielectric layer 40 directly contacting surface of the substrate 12 or fin-shaped structure 20. Specifically, each of the gate dielectric layers 40 formed on the core region 14 and I/O region 16 includes two vertical portions 42, 44 and a horizontal portion 46 connecting the two vertical portions 42, 44, in which the width or thickness of each of the vertical portions 42, 44 extending along horizontal direction is less than the thickness of the horizontal portion 46 extending along vertical direction. In this embodiment, the volume of oxygen gas injected during the oxide growth process is between 20-24 standard liter per minute (slm) or most preferably 22 slm and the duration for injecting the oxygen gas is between 20-25 seconds.

It should further be noted that whether the spacer 28 were to be a single or composite spacer, the innermost portion of the spacer directly contacting the gate dielectric layer 40 is preferably made of SiCN. By doing so, the oxygen gas injected during the aforementioned oxide growth process would react with inner sidewalls of the spacers 28 made of SiCN to form vertical portions 42, 44 of the gate dielectric layer 40 made of silicon oxycarbonitride (SiOCN) and at the same time react with fin-shaped structure 20 or substrate 12 surface made of silicon to form horizontal portions 46 of the gate dielectric layers 40 made of silicon oxide. In other words, after the oxygen gas injected during the oxide growth process reacts with inner sidewalls of the spacers 28 and surface of fin-shaped structure 20 or substrate 12 to form the gate dielectric layer 40, the two vertical portions 42, 44 and the horizontal portion 46 are preferably made of different materials, in which the two vertical portions 42, 44 are both made of SiOCN while the horizontal portion 46 is made of silicon oxide.

Next, as shown in FIG. 4, a patterned mask 48 such as patterned resist is formed on the I/O region 16 to expose the ILD layer 36 and gate dielectric layer 40 on the core region 14.

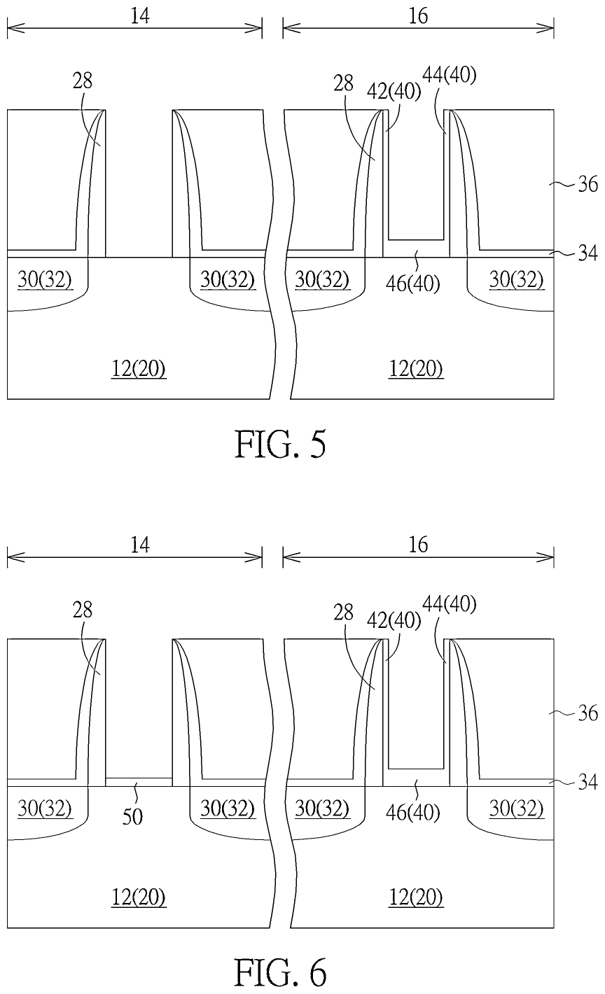

Next, as shown in FIG. 5, an etching process is conducted by using the patterned mask 48 as mask to remove the entire gate dielectric layer 40 on the core region 14 for exposing inner sidewalls of the spacer 28 and surface of the fin-shaped structure 20 or substrate 20. The patterned mask 48 is removed thereafter.

Next, as shown in FIG. 6, another oxide growth process such as a RTO process or an ISSG process could be conducted without forming additional patterned mask to form another gate dielectric layer 50 on fin-shaped structure or substrate 12 of the core region 14. It should be noted that the volume of oxygen gas and duration of the oxide growth process conducted at this stage is preferably adjusted to be slightly less than the volume of oxygen gas and duration of the oxide growth process conducted in FIG. 3 so that the injected oxygen gas only reacts with the fin-shaped structure 20 or substrate 12 surface but not reacting with inner sidewalls of the spacer 28 to form the gate dielectric layer 50. In other words, the gate dielectric layer 50 formed on the core region 14 at this stage is only formed on the surface of the fin-shaped structure 20 or substrate 12 surface but not on inner sidewalls of the spacer 28. Since oxygen gas only reacts with surface of the fin-shaped structure 20 or substrate 12, the gate dielectric layer 50 formed at this stage is preferably made of silicon oxide.

After the oxide growth process is conducted, gate dielectric layers 50, 40 are formed on the core region 14 and I/O region 16 respectively, in which the gate dielectric layer 50 on the core region 14 and the gate dielectric layer 40 on the I/O region 16 preferably have different shapes. Specifically, the gate dielectric layer 50 on the core region 14 includes an I-shape cross-section extending along horizontal direction, the gate dielectric layer 40 on the I/O region 16 includes a U-shape cross-section, and the thickness of the gate dielectric layer 50 on the core region 14 is greater than the thickness of either one of the vertical portions 42, 44 on the I/O region 16 but less than the thickness of the horizontal portion 46 on the I/O region 16. In this embodiment, the thickness of the gate dielectric layer 50 is between 6-8 Angstroms or most preferably 7 Angstroms, the thickness of the vertical portion 42 or vertical portion 44 of the gate dielectric layer 40 on the I/O region 16 is between 4-6 Angstroms or most preferably 5 Angstroms, and the thickness of the horizontal portion 46 of the gate dielectric layer 40 on the I/O region 16 is between 30-40 Angstroms or most preferably 34 Angstroms.

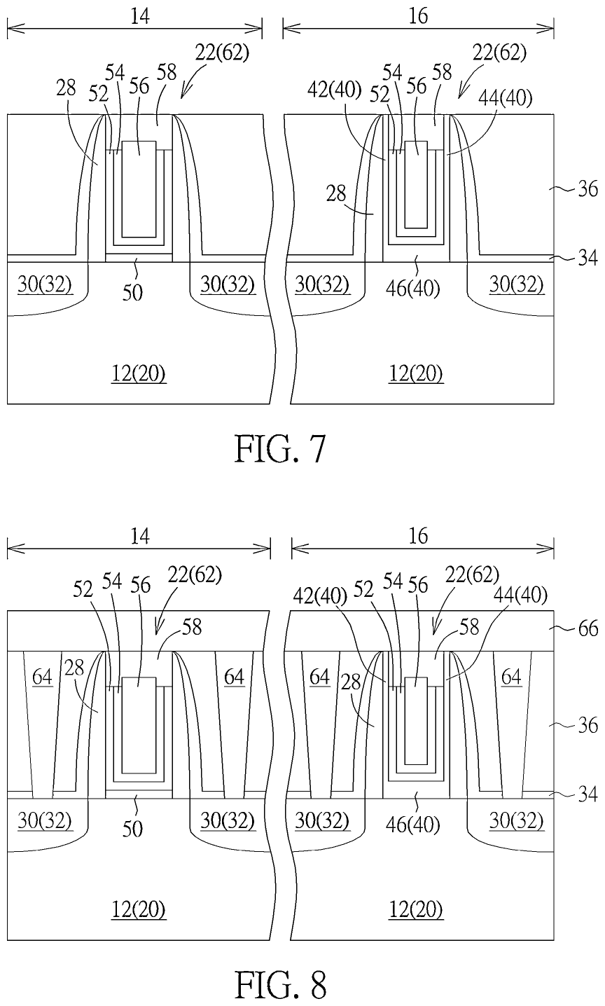

Next, as shown in FIG. 7, a high-k dielectric layer 52, a work function metal layer 54, and a low resistance metal layer 56 are sequentially formed in the recess 38, and a planarizing process, such as CMP is conducted to remove part of the low resistance metal layer 56, part of the work function metal layer 54, and part of the high-k dielectric layer 52 to form metal gates 62.

In this embodiment, the high-k dielectric layer 52 is preferably selected from dielectric materials having dielectric constant (k value) larger than 4. For instance, the high-k dielectric layer 52 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof. Preferably, the BBM layer 40 is selected from the group consisting of TiN and TaN, but not limited thereto.

In this embodiment, the work function metal layer 54 is formed for tuning the work function of the later formed metal gates to be appropriate in an NMOS or a PMOS. For an NMOS transistor, the work function metal layer 54 having a work function ranging between 3.9 eV and 4.3 eV may include titanium aluminide (TiAl), zirconium aluminide (ZrAl), tungsten aluminide (WA1), tantalum aluminide (TaAl), hafnium aluminide (HfAl), or titanium aluminum carbide (TiAIC), but it is not limited thereto. For a PMOS transistor, the work function metal layer 54 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 54 and the low resistance metal layer 56, in which the material of the barrier layer may include titanium (Ti), titanium nitride (TiN), tantalum (Ta) or tantalum nitride (TaN). Furthermore, the material of the low-resistance metal layer 56 may include copper (Cu), aluminum (Al), titanium aluminum (TiAl), cobalt tungsten phosphide (CoWP) or any combination thereof.

Next, part of the high-k dielectric layer 52, part of the work function metal layer 54, and part of the low resistance metal layer 56 could be removed to form a recess (not shown), and a hard mask 58 could be formed in the recess so that the top surfaces of the hard mask 58 and ILD layer 36 are coplanar. The hard mask 58 could be selected from the group consisting of silicon oxide, silicon nitride, silicon oxynitride, and silicon carbon nitride. It should be noted when part of the high-k dielectric layer 52, part of the work function metal layer 54, and part of the low resistance metal layer 56 are removed to form recesses, due to selectivity of the materials, the top surface of the low resistance metal layer 56 is preferably slightly higher than the top surface of the high-k dielectric layer 52 and the work function metal layer 54.

Next, as shown in FIG. 8, a contact plug formation could be conducted to form contact plugs 64 electrically connecting the source/drain regions 30 on the core region 14 and I/O region 16 and then a stop layer 66 is formed on the ILD layer 36. In this embodiment, the formation of contact plugs 64 could be accomplished by removing part of the ILD layer 36 and part of the CESL 34 to form contact holes (not shown), and then depositing a barrier layer (not shown) and a metal layer into the contact holes. A planarizing process such as CMP is then conducted to remove part of the metal layer, part of the barrier layer, and even part of the ILD layer 36 to form contact plugs 64 in the contact holes as the top surface of the contact plugs 64 is even with the top surface of the ILD layer 36. In this embodiment, the barrier layer is selected from the group consisting of Ti, Ta, TiN, TaN, and WN, the metal layer is selected from the group consisting of Al, Ti, Ta, W, Nb, Mo, and Cu, and the stop layer 66 preferably includes oxides such as tetraethyl orthosilicate (TEOS). This completes the fabrication of a semiconductor device according to an embodiment of the present invention.

Referring again to FIG. 8, FIG. 8 further illustrates a structural view of a semiconductor device according to an embodiment of the present invention. As shown in FIG. 8, the semiconductor device includes a substrate 12 having a core region 14 and an I/O region 16, a metal gate 62 disposed on the core region 14, another metal gate 62 disposed on the I/O region 16, spacers 28 disposed adjacent to the metal gates 62, and an ILD layer 36 disposed around the metal gates 62. Preferably, the metal gate 62 on the core region 62 includes a gate dielectric layer 50 disposed between the substrate 12 and the high-k dielectric layer 52, the metal gate 62 on the I/O region 16 includes a gate dielectric layer 40 disposed between the substrate 12 and the high-k dielectric layer 52, and the gate dielectric layer 50 and the gate dielectric layer 40 include different shapes.

Specifically, the gate dielectric layer 50 on the core region 14 includes an I-shape cross-section extending along horizontal direction while the gate dielectric layer 40 on the I/O region 16 includes a U-shape cross-section, in which the gate dielectric layer 40 on the I/O region 14 further includes two vertical portions 42, 44 and a horizontal portion 46 connecting the two vertical portions 42, 44 and the thickness of the gate dielectric layer 50 on the core region 14 is greater than the thickness of either one of the two vertical portions 42, 44 but less than the thickness of the horizontal portion 46.

Overall, the present invention first forms a gate structure or dummy gate made of polysilicon on core region and/or I/O region, forms an ILD layer around the gate structure, removes the gate structure made of polysilicon on each region to form recesses, and then conducts an oxide growth process to form a gate dielectric layer having U-shape cross-section in each recess. By adjusting volume of oxygen gas injected as well as duration of the oxide growth process, the oxygen gas could react with inner sidewalls of the spacer 28 and surface of the fin-shaped structure 20 or substrate 12 at the same time to form gate dielectric layers having U-shape cross-section. Evidently, the gate dielectric layer having U-shape cross-section could be used to repair or fill voids resulted from loss of epitaxial layer during wet etching process conducted during removal of the polysilicon gate structure.

It should be noted that even though a photo-etching process is conducted to remove the U-shape gate dielectric layer 40 on the core region as shown in FIGS. 4-5 and then form a thinner gate dielectric layer 50 afterwards, according to other embodiment of the present invention, it would also be desirable to form the U-shape gate dielectric layers 40 on the core region and I/O region as shown in FIG. 3 and then conduct the fabrication process shown in FIG. 7 directly without removing the U-shape gate dielectric layer on the core region. In other words, the high-k dielectric layer, work function metal layer, and low resistance metal layer would be formed on the U-shape gate dielectric layer on both core region and I/O region in this instance, which is also within the scope of the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating semiconductor device, comprising:
providing a substrate having a core region and an input/output (I/O) region; and
forming a first metal gate on the core region and a second metal gate on the I/O region, wherein the first metal gate comprises a first gate dielectric layer, the second metal gate comprises a second gate dielectric layer, and the first gate dielectric layer and the second gate dielectric layer comprise different shapes.

2. The method of claim 1, further comprising:
forming a first gate structure on the core region and a second gate structure on the I/O region;
forming a first spacer adjacent to the first gate structure and a second spacer adjacent to the second gate structure;
forming an interlayer dielectric (ILD) layer around the first gate structure and the second gate structure;
removing the first gate structure and the second gate structure to form a first recess on the core region and a second recess on the I/O region;
forming a third gate dielectric layer in the first recess and the second gate dielectric layer in the second recess;
forming a patterned mask on the I/O region;
removing the third gate dielectric layer in the first recess;
forming the first gate dielectric layer in the first recess; and
forming a high-k dielectric layer, a work function metal layer, and a low resistance metal layer in the first recess and the second recess for forming the first metal gate and the second metal gate.

3. The method of claim 2, wherein the second gate dielectric layer and the third gate dielectric layer comprise same shape.

4. The method of claim 2, wherein each of the second gate dielectric layer and the third gate dielectric layer comprises a U-shape.

5. The method of claim 1, wherein the first gate dielectric layer comprises an I-shape.

6. The method of claim 1, wherein the second gate dielectric layer comprises:
a first vertical portion and a second vertical portion; and
a horizontal portion connected the first vertical portion and the second vertical portion.

7. The method of claim 6, wherein the first vertical portion and the second vertical portion comprise same material.

8. The method of claim 6, wherein the first vertical portion and the horizontal portion comprise different materials.

9. A semiconductor device, comprising:
a substrate having a core region and an input/output (I/O) region; and
a first metal gate on the core region and a second metal gate on the I/O region, wherein the first metal gate comprises a first gate dielectric layer, the second metal gate comprises a second gate dielectric layer, and the first gate dielectric layer and the second gate dielectric layer comprise different shapes.

10. The semiconductor device of claim 9, further comprising:
a first spacer adjacent to the first metal gate and a second spacer adjacent to the second metal gate; and
an interlayer dielectric (ILD) layer around the first metal gate and the second metal gate.

11. The semiconductor device of claim 9, wherein the first gate dielectric layer comprises an I-shape.

12. The semiconductor device of claim 9, wherein the second gate dielectric layer comprises a U-shape.

13. The semiconductor device of claim 9, wherein the second gate dielectric layer comprises:
a first vertical portion and a second vertical portion; and
a horizontal portion connected the first vertical portion and the second vertical portion.

14. The semiconductor device of claim 13, wherein the first vertical portion and the second vertical portion comprise same material.

15. The semiconductor device of claim 13, wherein the first vertical portion and the horizontal portion comprise different materials.
